(19) United States
(12) Patent Application Publication
(10) Pub. No.: US 2020/0040480 A1
(43) Pub. Date: Feb. 6, 2020

(54) METHOD OF PRODUCING SILICON SINGLE CRYSTAL INGOT AND SILICON SINGLE CRYSTAL GROWTH APPARATUS

(71) Applicant: SUMCO CORPORATION, Tokyo (JP)

(72) Inventors: Wataru SUGIMURA, Tokyo (JP); Masataka HOURAI, Tokyo (JP)

(73) Assignee: SUMCO CORPORATION, Tokyo (JP)

(21) Appl. No.: 16/487,957

(22) PCT Filed: Jan. 11, 2018
(86) PCT No.: PCT/JP2018/000518

§ 371 Date: Aug. 22, 2019

(30) Foreign Application Priority Data
Feb. 28, 2017 (JP) 2017-037613

(51) Int. Cl. C30B 15/04; C30B 29/06; C30B 15/20; C30B 15/10

(52) U.S. Cl. CPC C30B 15/04; C30B 15/10; C30B 15/20; C30B 29/06

(57) ABSTRACT

Provided are a method of producing a high resistance n-type silicon single crystal ingot with small tolerance margin on specific resistance in the crystal growth direction, which is suitably used in a power device, and a silicon single crystal growth apparatus. In a method of producing a silicon single crystal ingot using Sb or As as an n-type dopant with the use of a silicon single crystal growth apparatus using the Czochralski process, a measurement step of measuring the gas concentration of a compound gas containing the n-type dopant as a constituent element; and a pulling condition controlling step of controlling one or more pulling condition values including at least one of a pressure in the chamber, a flow volume of the Ar gas, and a gap between the guide portion and the silicon melt so that the measured gas concentration falls within a target gas concentration range are performed.

### TECHNICAL FIELD

This disclosure relates to a method of producing a silicon single crystal ingot and a silicon single crystal growth apparatus. In particular, this disclosure relates to a method of producing an n-type silicon single crystal ingot suitably used to produce an n-type silicon wafer for insulated-gate bipolar transistors (IGBTs) and to a silicon single crystal growth apparatus.

### BACKGROUND

A silicon wafer used as a substrate of a semiconductor device is produced by cutting a silicon single crystal ingot grown by a silicon single crystal growth apparatus into thin slices and subjecting the slices to a surface grinding (lapping) step, an etching step, and a mirror polishing (polishing) step followed by final washing. A silicon single crystal having a large diameter of 300 mm or more is typically produced by the Czochralski (CZ) process. A silicon single crystal growth apparatus using the CZ process is also called as a silicon single crystal-pulling furnace or a CZ furnace, for example.

Of semiconductor devices, insulated-gate bipolar transistors (IGBTs) which are a type of power device are gate voltage driven switching devices suitable for high power control, and find use in electric trains, power supply, and vehicle-mounted applications, etc. In power device applications, such as IGBTs, n-type silicon wafers are used under the current circumstances, which wafers are obtained by slicing an n-type silicon single crystal ingot with a diameter of 200 mm doped with P (phosphorus), which is produced by the floating zone melting (FZ) process and the MCZ (Magnetic field applied Czochralski) process.

Here, since the n-type dopant does not segregate in a silicon single crystal ingot grown by the FZ process as illustrated in FIG. 1, almost the whole straight trunk of the ingot can be used as a product. However, the diameter of silicon single crystal ingots that can be stably produced by the FZ process is 150 mm, and it is difficult to produce silicon single crystal ingots having a diameter of 200 mm or more, particularly a large diameter of 300 mm by the FZ process.

On the other hand, P is typically used as a dopant practically used in n-type silicon single crystal ingots for power devices using the CZ process. The yield of n-type silicon wafers obtained from such a silicon single crystal ingot doped with P that meet the specifications including for example a specific resistance of 50 [Ω·cm]±10%, is approximately 10% at most in the current circumstances (see FIG.1), This is because since P has a segregation coefficient of less than 1, the P concentration (n-type dopant concentration) in the melt increase as the pulling of silicon single crystal proceeds, and the resistance gradually decreases. Since P has a segregation coefficient of 0.35, which is significantly higher than the segregation coefficient of B (boron) of 0.8, in the case of growing a crystal having resistance in a target range across the entire crystal length, the yield achieved using an n-type silicon single crystal ingots would be lower than the yield achieved using a p-type silicon single crystal ingot. Hence, techniques for improving the yield of silicon wafers obtained from an n-type silicon single crystal ingot have been diligently studied.

From the studies, it has also been proposed that Sb (antimony) or As (arsenic) of which evaporation rate is significantly higher than that of P is used as an n-type dopant although its segregation coefficient is even smaller than that of P. Tolerance margin on specific resistance of a silicon single crystal ingot can be reduced by reducing the pressure inside a chamber of a CZ furnace to accelerate evaporation of the n-type dopant and thereby compensating the segregation of the n-type dopant.

On the other hand, we propose, in JP 2010-059032 A (PTL 1), a method of producing a silicon wafer for vertical silicon devices by pulling up a silicon single crystal by the Czochralski process from a silicon melt to which Sb (antimony) or As (arsenic) is added as a volatile dopant, in which method the flow volume of Ar gas flowing along the surface of the silicon melt is increased with the process of the pulling of the silicon single crystal.

As described in PTL 1. since the surface of the silicon melt has a high concentration of gas containing the volatile dopant having been evaporated, the evaporation rate of the volatile dopant in the silicon melt depends on not only the pressure inside the chamber of the CZ furnace but also greatly on the flow volume of the Ar gas. Accordingly, the evaporation rate of the volatile dopant is controlled by controlling the flow volume of the Ar gas flowing on the melt surface by the technique described in PTL 1, thus segregation of the dopant can be compensated.

### CITATION LIST

### Patent Literature

PTL 1: JP 2010-059032

### SUMMARY

### Technical Problem

The allowable resistance tolerance margin in a silicon wafer for power devices such as IGBTs is significantly small and the tolerance margin has conventionally been ±10% with respect to the average specific resistance.

In recent years, however, the tolerance margin is required to be approximately ±8%, and a desired tolerance margin is going to be in a range of ±7% or less in the future. Although the technique described in PTL 1 made it possible to control the evaporation rate of an n-type dopant to some extent, there is room for improvement in achieving the tolerance margin to be required in the future at high yield in the crystal growth direction.

It could therefore be helpful to provide a method of producing a high resistance n-type silicon single crystal ingot with small tolerance margin on specific resistance in the crystal growth direction, which is suitably used in a power device, and to provide a silicon single crystal growth apparatus.

### Solution to Problem

We made diligent studies to achieve the above objectives. We contemplated controlling to keep the n-type dopant concentration in the silicon melt constant in order to further reduce tolerance margin on specific resistance of a crystal in the growth direction in the growth of an n-type silicon single crystal using the volatile n-type dopant, described in PTL 1. To perform such control, the n-type dopant is required to be evaporated from the melt surface by an amount equivalent to the amount of the n-type dopant being concentrated in the melt by segregation. Accordingly, we first considered keeping a fixed evaporation rate of the n-type dopant from the silicon melt while pulling up the crystal. Note that evaporation of the n-type dopant from the melt is considered to be evaporation of the dopant in the form of gas of the dopant element alone or gas of a compound such as phosphorus oxide (PₓO_{y}), antimony oxide (SbₓO_{y}), arsenic oxide (AsₓO_{y}), or the like. Conceivably, such an oxide is formed in the silicon melt by a combination of feedstock silicon and oxygen having been dissolved from the quartz crucible and is discharged from the surface of the silicon melt in the form of gas.

The evaporation rate of the n-type dopant on the melt surface directly depends on the flow rate of Ar gas directly on the melt. This is because the concentration gradient of the compound of the n-type dopant in the concentration boundary layer in the vicinity of a gas-liquid interface on the gas-phase side (in which mass transfer is possible only by diffusion) depends on the Ar gas flow rate directly on the concentration boundary layer. Accordingly, as the Ar gas flow rate increases, the concentration gradient of the compound of the n-type dopant increases, and the evaporation amount of the compound of the n-type dopant evaporated from the melt also increases. Thus, in order to control the evaporation rate of the n-type dopant, the flow rate of Ar gas directly on the silicon melt is required to be controlled.

Given this situation, we contemplated measuring the gas concentration of the dopant gas containing, as a constituent element, an n-type dopant discharged in the form of gas in a CZ furnace, and controlling the Ar gas flow rate so that the gas concentration can be constant. The dopant gas concentration measured during the growth of silicon directly reflects the concentration of the n-type dopant evaporated from the silicon melt surface. The gas concentration of the dopant gas is measured in-situ, and the Ar gas flow rate is controlled so that the gas concentration can be maintained in an appropriate range by changing the process conditions, thus a silicon single crystal ingot which makes it possible to obtain silicon wafers at high yield can be produced.

We found that performing such control can make the dopant concentration in the silicon single crystal ingot uniform in the crystal growth direction, and tolerance margin on specific resistance of the silicon single crystal ingot in the crystal growth direction can be significantly reduced as compared with that obtained by conventional techniques. Further, a silicon single crystal ingot having a given specific resistance in the crystal growth direction can be grown by changing the gas concentration as desired during silicon growth. This disclosure completed based on the above findings primarily includes the following features.

(1) A method of producing a silicon single crystal ingot using a silicon single crystal growth apparatus having a crucible storing a silicon melt doped with an n-type dopant, a chamber accommodating the crucible, a pressure regulator controlling a pressure in the chamber, a pulling portion pulling up a silicon single crystal ingot from the silicon melt, a gas supply for supplying

Ar gas into the chamber, a gas exhaust through which the Ar gas is discharged from the chamber, and a guide portion provided above a surface of the silicon melt for guiding the Ar gas to flow along the surface of the silicon melt, comprising:

a pulling step of pulling up the silicon single crystal ingot by the Czochralski process;

a measurement step of measuring a gas concentration of a dopant gas containing the n-type dopant as a constituent element while performing the pulling step; and

a pulling condition controlling step of controlling one or more pulling condition values including at least one of the pressure in the chamber, a flow volume of the Ar gas, and a gap between the guide portion and the silicon melt while performing the pulling step so that the measured gas concentration falls within a target gas concentration range.

(2) The method of producing a silicon single crystal ingot, according to (1) above, wherein the target gas concentration is uniform in a crystal growth direction.

(3) The method of producing a silicon single crystal ingot, according to (1) or (2) above, wherein in the measurement step, the gas concentration of the dopant gas discharged with the Ar gas on the Ar gas outlet side is measured.

(4) The method of producing a silicon single crystal ingot, according to any one of (1) to (3) above, wherein the gas concentration of the dopant gas is measured using a mass spectrometer.

(5) The method of producing a silicon single crystal ingot, according to any one of (1) to (4) above, wherein the n-type dopant is one of Sb and As.

(6) A silicon single crystal growth apparatus comprising: a crucible storing a silicon melt doped with an n-type dopant; a lifting and rotating mechanism which is provided on a lower end of the crucible to rotate, raise, and lower the crucible; a chamber accommodating the crucible; a pressure regulator controlling a pressure in the chamber; a pulling portion pulling up a silicon single crystal ingot from the silicon melt by the Czochralski process, a gas supply for supplying Ar gas into the chamber; a gas exhaust through which the Ar gas is discharged from the chamber; and a guide portion provided above a surface of the silicon melt for guiding the Ar gas to flow along the surface of the silicon melt, further comprising a measurement unit for measuring the gas concentration of the dopant gas containing the n-type dopant as a constituent element discharged with the Ar gas on the Ar gas outlet side.

(7) The silicon single crystal growth apparatus according to (6) above, wherein the measurement unit is a mass spectrometer.

(8) The silicon single crystal growth apparatus according to (6) or (7) above, further comprising a control unit controlling the lifting and rotating mechanism, the pressure regulator, the pulling portion, the gas supply, and the measurement unit,

wherein one or more pulling condition values including at least one of the pressure in the chamber, a flow volume of the Ar gas, and a gap between the guide portion and the silicon melt are controlled using the control unit while performing the pulling so that the gas concentration measured by the measurement unit falls within a target gas concentration range.

(9) The silicon single crystal growth apparatus according to any one of (6) to (8) above, wherein the n-type dopant is one of Sb and As.

### Advantageous Effect

This disclosure provides a method of producing a high resistance n-type silicon single crystal ingot with small tolerance margin on specific resistance in the crystal growth direction, which is suitably used in a power device, and a silicon single crystal growth apparatus.

### BRIEF DESCRIPTION OF THE DRAWINGS

In the accompanying drawings:

FIG. 1 is a schematic view illustrating tolerance margin on specific resistance of silicon single crystal ingots obtained by conventional techniques;

FIG. 2 is a schematic view depicting a silicon single crystal pulling furnace used in one embodiment of this disclosure;

FIG. 3 is a graph illustrating the SbO concentration relative to the crystal length in Examples; and

FIG. 4 is a graph illustrating the distribution of the specific resistance relative to the crystal length of each silicon single crystal ingot prepared in Examples.

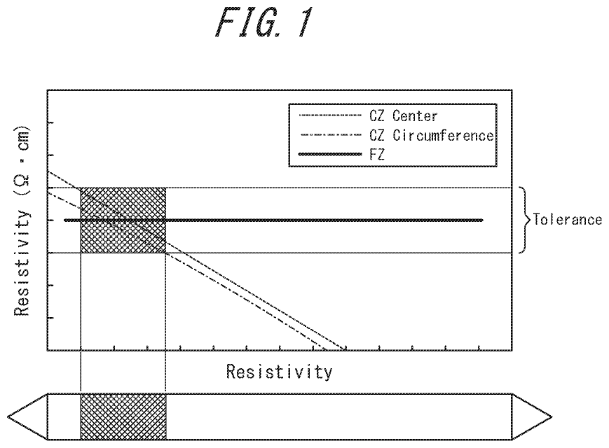

### DETAILED DESCRIPTION

(Method of Producing Silicon Single Crystal Ingot)

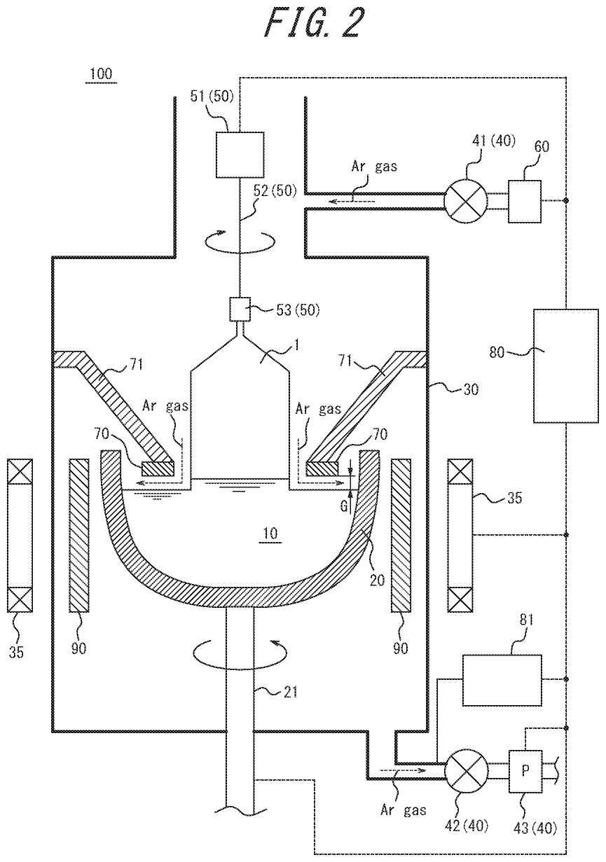

A method of producing a silicon single crystal ingot according to one embodiment of this disclosure can be performed using a silicon single crystal growth apparatus 100 schematically illustrated in FIG. 2. This silicon single crystal growth apparatus 100 at least has a crucible 20 storing a silicon melt 10, a chamber 30 accommodating the crucible 20, a pressure regulator 40 controlling the pressure in the chamber 30 (hereinafter “furnace pressure”), a pulling portion 50 pulling up a silicon single crystal ingot 1 from the silicon melt 10, a gas supply 60 for supplying Ar gas into the chamber 30, a gas exhaust through which the Ar gas is discharged from the chamber 30, and a guide portion 70 provided above the surface of the silicon melt 10 for guiding the Ar gas to flow along the surface of the silicon melt 10, and optionally has other components. Here, an n-type dopant is added to the silicon melt 10 in the silicon single crystal growth apparatus 100. Note that one or more of P (phosphorus), As (arsenic), and Sb (antimony) can be used as the n-type dopant.

The production method according to this embodiment includes a pulling step of pulling up the silicon single crystal ingot 1 by the Czochralski process; a measurement step of measuring a gas concentration of a dopant gas containing the n-type dopant as a constituent element while performing the pulling step; and a pulling condition controlling step of controlling one or more pulling condition values including at least one of a pressure in the chamber 30, a flow volume of the Ar gas, and a gap between the guide portion 70 and the silicon melt 10 (hereinafter, gap G) while performing the pulling step so that the measured gas concentration falls within a target gas concentration range. These steps will be sequentially described in detail below.

The pulling step can be performed by a conventionally known technique using the CZ process. In this embodiment, while performing the pulling step, the above measurement step is performed; meanwhile, the above pulling condition controlling step is performed using the gas concentration measured in the measurement step. Note that “controlling so that the measured gas concentration falls within a target gas concentration range” in the pulling condition controlling step means to control one or more pulling condition values to keep the gas concentration during measurement within a desired gas concentration range. When the target gas concentration is a desired gas concentration CG, keeping the variation in gas concentration within the range of C_{G}±10% is involved by “controlling so that the measured gas concentration falls within a target gas concentration range”, and the variation in the gas concentration is preferably kept within the range of C_{G}±8% , and the variation in the gas concentration is more preferably kept within the range of C_{G}±7%.

The target concentration is preferably uniform in the crystal growth direction. This allows the specific resistance to be almost uniform over the entire area in the crystal growth direction. However, the target concentration may be gradually increased or decreased depending on the length of the crystal being pulled up; alternatively, the target concentration may be increased or decreased depending on crystal length brackets. Thus, a single crystal silicon ingot having a given specific resistance in the crystal growth direction can be obtained.

As described above, the gas concentration of a dopant gas containing the n-type dopant as a constituent element is measured in the measurement step while performing the pulling step. In this measurement step, it is preferred to measure the concentration of the gas containing the n-type dopant discharged with the Ar gas on the Ar gas outlet side. The n-type dopant evaporated from the silicon melt 10 is a gas of phosphorus alone, arsenic alone, or antimony alone; or a phosphorus compound (PₓO_{y} etc.), an antimony compound (SbₓO_{y} etc.), or an arsenic compound (AsₓO_{y} etc.). When the n-type dopant is Sb, mainly a gas of Sb alone, SbO gas, and Sb₂O₃ gas are simultaneously discharged along with the Ar gas, in which case the gas concentration of one of Sb, SbO gas, and Sb₂O₃ gas may be measured; alternatively, the gas concentration of two or more of them may be analyzed.

Such a measurement step can be performed by providing a measurement unit 81 for measurement using infrared spectroscopy or mass spectrometry on the Ar gas outlet side of the silicon single crystal growth apparatus 100, and performing gas analysis of the dopant gas containing the n-type dopant discharged with the Ar gas using the measurement unit 81. The measurement unit 81 preferably uses a mass spectrometer; for example, a quadrupole mass spectrometer (QMS) can be used, or an infrared spectrometer may be used instead. When a quadrupole mass spectrometer is used in particular, quantitative analysis of the dopant gas containing a subject n-type dopant as a constituent element can be performed more reliably with more precision. For example, when the gas concentration of SbO gas is measured, the pulling condition controlling step is performed so that the gas concentration of SbO gas is kept constant from the initial stage of the growth of the ingot 1.

Note that the measurement step is preferably performed at all times from the melting of polysilicon feedstock to the cooling of the crystal during the pulling step; alternatively, the measurement step may be performed every several ten seconds or every several minutes. During the pulling step, performing the measurement step at all times to reflect the measurement results in the pulling condition controlling step is preferred since the variation in the gas concentration of the dopant gas, that is, the variation in the dopant concentration in the crystal growth direction of the silicon single crystal ingot 1 can be reduced.

Here, the flow rate of Ar on the silicon melt 10 is inversely proportional to the furnace pressure, directly proportional to the Ar flow volume, and inversely proportional to the gap G This being the case, in the pulling condition controlling step, one or more pulling condition values including at least one of the furnace pressure, the flow volume of the Ar gas, and the gap G is controlled so that the gas concentration of the dopant gas measured in the above measurement step falls within a target concentration range.

Specifically, based on change in the measured gas concentration with time, when the gas concentration is close to the lower limit of the target gas concentration range, one or more of reducing the furnace pressure, increasing the Ar flow volume, and reducing the gap may be performed in order to accelerate the evaporation of the n-type dopant. Further, all those three control factors are not necessarily controlled to accelerate evaporation; for example, the adjustment may be performed by increasing the furnace pressure for fine adjustment, and increasing or reducing the gap G while increasing the Ar flow rate.

By contrast, when the measured gas concentration exceeds the target constant concentration, in order to inhibit evaporation of the n-type dopant, one or more of increasing the furnace pressure, reducing the Ar flow rate, and increasing the gap G may be performed. Further, all those three control factors are not necessarily controlled to inhibit evaporation; for example, the adjustment may be performed by, while reducing the Ar flow volume, reducing the furnace pressure for fine adjustment, and increasing or reducing the gap G.

While the measured gas concentration is kept at a target constant concentration, the pulling condition values can be maintained. Note that in terms of control of the gas concentration, both the furnace pressure and the flow volume of Ar gas are preferably adjusted. Preferably, the gas concentration is first adjusted by controlling only the Ar flow volume, and if the target concentration is not likely to be achieved, the furnace pressure is controlled. Alternatively, it is also preferred to adjust the gas concentration by first controlling only the Ar flow volume and optionally controlling the furnace pressure if the gas concentration is not likely to exceed the target concentration.

Further, the target constant concentration may be determined by previously determining the relationship between the target specific resistance of the silicon single crystal ingot 1 and the gas concentration of the dopant gas, and selecting a gas concentration for the desired specific resistance based on the correspondence. In addition, the gas concentration of the dopant gas at a given time during the growth of the silicon single crystal ingot 1 may be maintained. It is also preferred that the gas concentration of the dopant gas at a time in the initial stage of the growth is maintained so that the gas concentration is kept at a constant concentration during the growth.

Note that this embodiment can be applied to cases where the n-type dopant is any one of P, As, or Sb, and is more effectively applied to the case where As or Sb is used, yet is particularly effectively applied to the case of using Sb. This is because the rates of evaporation of Sb, As, and P from the silicon melt are ranked from high to low is this order.

Preferably, in the pulling step, the ratio of v/G is controlled to for example around 0.22 to 0.27, where the growth rate of the ingot 1 is v [mm/min] and the temperature gradient from the melting point to 1350° C. during the growth of a single crystal for the ingot 1 is G [° C./mm]. When v/G exceeds this range, COPs and voids are easily formed, and when the ratio is lower than this range, dislocation clusters are easily formed.

According to this embodiment, controlling the evaporation rate of the n-type dopant can improve the resistance yield in the crystallographic axis direction of the n-type silicon single crystal ingot 1, and besides, the crystal cost can be reduced. Further, maintaining the gas concentration of the dopant gas accelerates evaporation of a compound of the n-type dopant as compared with the case where no significant control is performed, so that the Ar flow rate on the surface of the silicon melt 10 is increased; accordingly, carbon contamination (contamination and buildup of CO gas caused when CO gas produced by a reaction between a carbon member of a heater etc. and SiO volatilized from the melt flows back to the melt) is expected to be reduced.

An n-type silicon single crystal ingot 1 having a specific resistance in the range of 10 Ω·cm or more and 1000 Ω·cm or less, and a crystal diameter of 200 mm or more, 40% or more of which ingot has the specific resistance in the range of ±7% of a specification specific resistance in the crystal growth direction can be produced in accordance with the production method of this embodiment. Note that the specific resistance covers the specific resistance of only the straight trunk of the ingot excluding a neck portion, a crown portion, and a tail portion of the ingot which do not constitute a product. In particular, this production method is preferably used to produce the silicon single crystal ingot 1 having a specific resistance of 50 Ω·cm or more, is also preferably used to produce the silicon single crystal ingot 1 having a crystal diameter of 300 mm or more, and is yet preferably used to produce the silicon single crystal ingot 1, 40% or more of which has a specific resistance in the range of ±7% of the specification specific resistance in the crystal growth direction.

(Silicon Single Crystal Growth Apparatus)

Next, the silicon single crystal growth apparatus 100 which is effectively used in the above embodiment of the production method will be described. Like components are denoted by the same reference numerals as in the above embodiment, and repetitive description of the components is omitted herein.

The silicon single crystal growth apparatus 100 according to one embodiment of this disclosure has a crucible 20 storing a silicon melt 10 doped with an n-type dopant; a lifting and rotating mechanism 21 which is provided on a lower end of the crucible 20 to rotate, raise, and lower the crucible 20; a chamber 30 accommodating the crucible 20; a pressure regulator 40 controlling the pressure in the chamber 30; a pulling portion 50 pulling up the silicon single crystal ingot 1 from the silicon melt 10 by the Czochralski process, a gas supply 60 for supplying Ar gas into the chamber 30; a gas exhaust through which the Ar gas is discharged from the chamber 30; and a guide portion 70 provided above the surface of the silicon melt 10 for guiding the Ar gas to flow along the surface of the silicon melt 10.

The silicon single crystal growth apparatus 100 further has a measurement unit 81 for measuring the gas concentration of a dopant gas containing the n-type dopant as a constituent element on the Ar gas outlet side. These features will be sequentially described in detail below.

<N-type Dopant>

The n-type dopant used may be one of P, As, and Sb, preferably one of As and Sb, particularly preferably Sb.

<Silicon Melt>

The silicon melt 10 is feedstock for the silicon single crystal ingot 1. The feedstock is typically polysilicon, and the feedstock is melted by for example the heater 90 provided on the circumference of the crucible 20 to maintain the state of the melt. Nitrogen may be added to the silicon melt in addition to the n-type dopant.

<Crucible>

The crucible 20 stores the silicon melt 10 and may have a dual structure typically including an inner quartz crucible and an outer carbon crucible.

<Lifting and Rotating Mechanism>

The lifting and rotating mechanism 21 is provided on the lower end of the crucible 20. The lifting and rotating mechanism 21 can perform lifting and rotation and perform control of the gap G with the use of the control unit 80. The direction of rotation of the lifting and rotating mechanism 21 is typically a reverse direction to the rotation direction of the pulling portion 50.

<Chamber>

The chamber 30 accommodates the crucible 20, and usually the Ar gas supply 60 is provided above the chamber 30 and the Ar gas exhaust is provided at the bottom of the chamber 30. Further, the chamber 30 may include the guide portion 70 and a heat shielding member 71, and a heater 90 and features typically used in a CZ furnace which are not shown. Although FIG. 2 illustrates this aspect, the arrangement of the components is not limited to the arrangement in the diagram.

<Ar Gas Supply and Ar Gas Exhaust>

Ar gas can be supplied through a valve 41 into the chamber 30, and can be discharged from the chamber 30 through a valve 42. The valves 41, 42, and a vacuum pump 43 constitute the pressure regulator 40, which can control the Ar gas flow volume. A supply source of Ar gas can be placed upstream of the valve 41, and the supply source serves as the gas supply 60. Further, Ar gas is discharged using the pump 43, and the pump 30 can also serve as the Ar gas exhaust. At the same time as the discharge of Ar gas, the dopant gas also flows to the outlet.

<Pulling Portion>

The pulling portion 50 may have a wire winding mechanism 51, a pulling wire 52 wound by the wire winding mechanism 51, and a seed chuck 53 for retaining the seed crystal, thus the above pulling step can be performed.

<Guide Portion>

The guide portion 70 may be constituted by the end portion of the heat shielding member 71 on the silicon melt 10 side. The guide portion 70 may have a shape with a sharp angle unlike in FIG. 2. The gap between the guide portion 70 and the silicon melt 10 in the height direction is the gap G described above. Further, it is also preferred that a guide plate is provided separately as the guide portion 70 along the surface of the melt on the end portion of the heat shielding member 71. The guide plate helps to guide the Ar gas to the outside along the surface of the silicon melt 10, which makes it easier to control the flow rate of the Ar gas. In this case, the gap G is the distance between the surface of the silicon melt 10 and the guide plate. The heat shielding member 71 can prevent heating of the silicon ingot 1 and suppress changes in the temperature of the silicon melt 10.

<Measurement Unit >

The measurement unit 81 performs measurement of the gas concentration of the dopant gas containing the n-type dopant as a constituent element by infrared spectroscopy or mass spectrometry as described above.

The measurement unit 81 preferably uses a mass spectrometer; for example, a quadrupole mass spectrometer (QMS) can be used. This allows for fast separation of a large volume of gas and makes it possible to reduce the size of the apparatus. Alternatively, an infrared spectrometer may be used. The measurement unit is preferably provided to be connected to a pipe upstream of the valve 42. Although not shown, the gas analyzed by the measurement unit 81 can be recovered between the valve 42 and the pump 43.

<Magnetic Field Supply Unit>

It is also preferred that a magnetic field supply unit 35 is provided outside the chamber 30. The magnetic field supplied by the magnetic field supply unit 35 may be one of a horizontal magnetic field and a cusp magnetic field.

<Control Unit>

The silicon single crystal growth apparatus 100 preferably further has a control unit 80 controlling the above-mentioned lifting and rotating mechanism 21, the pressure regulator 40, the pulling portion 50, the gas supply 60, and the measurement unit 81. The silicon single crystal growth apparatus 100 preferably controls one or more pulling condition values including at least one of the pressure in the chamber 30 (furnace pressure), the flow volume of the Ar gas, and the distance between the guide portion 70 and the silicon melt 10 (gap G) using the control unit 80 while performing the pulling of the silicon single crystal ingot 1 so that the gas concentration of the dopant gas measured by the measurement unit 81 is kept at a constant concentration.

The control unit 80 is implemented by a suitable processor such as a central processing unit (CPU) or an MPU. The control unit 80 may have a storage unit such as a memory or a hard disk. Further, the control unit 80 controls the transmittance of information and instructions between the components of the silicon single crystal growth apparatus 100 and the operation of each unit by executing programs for performing the above production method previously stored in the control unit 80.

A high resistance n-type silicon single crystal ingot with small tolerance margin on specific resistance in the crystal growth direction, which is suitably used in a power device can be obtained by producing a silicon single crystal ingot using the silicon single crystal growth apparatus 100 according to one embodiment of this disclosure described above.

### EXAMPLES

Next, in order to clarify the effects of this disclosure, an example is given below; however, this disclosure is not limited to the following example in any way.

### Example 1

A silicon single crystal ingot with a diameter of 300 mm and a straight trunk length of 1800 mm was grown by the CZ process using the silicon single crystal growth apparatus 100 depicted in FIG. 2. First, 350 kg of polysilicon feedstock is charged into a 32 in quartz crucible 20, and the polysilicon feedstock was melted in an argon atmosphere. Next, Sb (antimony) was added as an n-type dopant. At this time, the dopant amount was controlled so that the specific resistance of the starting end of the straight trunk of the silicon single crystal ingot would he 50 Ω·cm. Note that the target specific resistance of the crystal was 50Ω·cm ±7% in the axis direction. A seed crystal was then immersed in the silicon melt 10, and the seed crystal was gradually pulled up while rotating the quartz crucible 20, thus a dislocation-free silicon single crystal was grown under the seed crystal. Here, the ratio V/G was set to approximately 0.27, where the growth rate of the single crystal was V and the temperature gradient from the melting point at the solid-liquid interface, which was the boundary between the silicon crystal and the melt to 1350° C. was G (° C./min).

During the growth of the crystal, the concentration of the gas of the dopant generated from the surface of the silicon melt 10 was continuously measured. A quadrupole gas analyzer system was used for the gas analysis. The gas species to be analyzed was SbO. The position of the silicon single crystal growth apparatus 100 at which the gas was collected was a pipe upstream of the electromagnetic valve 42 depicted in FIG. 2. The gas in the silicon single crystal growth apparatus 100 was drawn into the gas mass analyzer system through a port for gas to be analyzed with a diameter of 10 mm. During the crystal growth, the gas in the pulling apparatus was continuously drawn and change in the gas concentration of SbO contained in the effluent gas discharged with Ar gas was monitored.

The Ar gas flow volume was 120 L/min and the furnace pressure was 30 Torr in the initial stage where the straight trunk portion was started to be grown. The Ar gas flow volume was adjusted according to the following formula so that the target SbO concentration (300 ppm in Example 1) at 60 min intervals.

$$[ Ar flow volume after adjustment ] = [ \begin{matrix}Ar flow volume at \\ time of adjustment\end{matrix} ] \times \frac{[ Target SbO concentration ]}{[ SbO concentration at time of adjustment ]}$$

### Comparative Example 1

A silicon single crystal ingot was grown in the same manner as in Example 1 except that the Ar gas flow volume was kept at 120 L/min and the furnace pressure was kept at 30 Torr during the crystal growth.

### Comparative Example 2

The furnace pressure was 30 Torr at the start of the growth, and was gradually reduced from 30 Torr to 10 Torr until a crystal length of 1800 mm was achieved. Further, the Ar flow volume was set to 120 L/min at the start of the growth, and was gradually increased from 120 L/min to 180 L/min until a crystal length of 1800 mm was achieved. A silicon single crystal ingot was grown under the same conditions as in Example 1 except for the above conditions.

<Change in SbO Concentration>

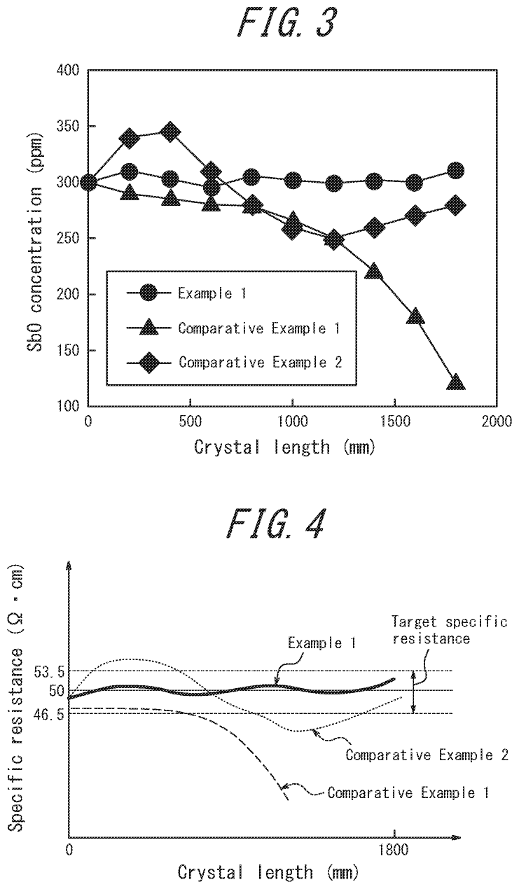

The changes in the SbO concentration in Example 1 and Comparative Examples 1 and 2 are illustrated in the graph of FIG. 3. Note that the obtained measurement results were organized based on the crystal length, Example 1 demonstrated that the change in the concentration was within the range of ±4% from the SbO initial concentration of 300 ppm and the SbO concentration was kept constant. In Comparative Examples 1 and 2, the SbO concentration was not constant.

<Measurement Results of Specific Resistance of Crystal>

The grown silicon single crystal ingot was cut into 200 mm thick wafers from the starting end of the straight trunk (0 mm), and heat treatment was then performed at 650° C. to completely annihilate donors in the wafers. Next, the specific resistance of the center of each wafer was measured by a testing method using a four-point probe array. The measured specific resistance organized based on the crystal length is illustrated in FIG. 4.

<Method of Calculating Yield>

Here, the topmost 100 mm of the crystal was subtracted from the block length [mm] of a resistance range, and the difference was divided by 1800 [mm] that was the total block length. The percentage of the calculated value was defined as the crystal yield [%]. The crystal yield was as follows.
Example 1: (1700 [mm]/1800 [mm])×100=94.4 [%]
Comparative Example 1: (520 [mm]/1800 [mm])×100=28.9 [%]
Comparative Example 2: (610 [mm]/800 [mm])×100=33.9 [%]

The above results demonstrated that a high resistance n-type silicon single crystal ingot with small tolerance margin on average resistance was produced in Example 1 in which SbO, which was the dopant gas of the n-type dopant, was kept at a constant concentration.

### INDUSTRIAL APPLICABILITY

This disclosure can provide a method of producing a high resistance n-type silicon single crystal ingot with small tolerance margin on average resistance, which is suitably used in a power device.

### REFERENCE SIGNS LIST

1 Silicon single crystal ingot

10 Silicon melt

20 Crucible

21 Lifting and rotating mechanism

30 Chamber

35 Magnetic field supply unit

40 Pressure regulator

50 Pulling portion

60 Ar gas supply

70 Guide portion

80 Control unit

81 Measurement unit

90 Heater

100 Silicon single crystal growth apparatus

G Gap

1. A method of producing a silicon single crystal ingot using a silicon single crystal growth apparatus having a crucible storing a silicon melt doped with an n-type dopant, a chamber accommodating the crucible, a pressure regulator controlling a pressure in the chamber, a pulling portion pulling up a silicon single crystal ingot from the silicon melt, a gas supply for supplying Ar gas into the chamber, a gas exhaust through which the Ar gas is discharged from the chamber, and a guide portion provided above a surface of the silicon melt for guiding the Ar gas to flow along the surface of the silicon melt, comprising:
pulling up the silicon single crystal ingot by the Czochralski process;
measuring a gas concentration of a dopant gas containing the n-type dopant as a constituent element while performing the pulling; and
controlling one or more pulling condition values including at least one of the pressure in the chamber, a flow volume of the Ar gas, and a gap between the guide portion and the silicon melt while performing the pulling so that the measured gas concentration falls within a target gas concentration range.

2. The method of producing a silicon single crystal ingot, according to claim 1, wherein the target gas concentration is uniform in a crystal growth direction.

3. The method of producing a silicon single crystal ingot, according to claim 1, wherein during the measuring, the gas concentration of the dopant gas discharged with the Ar gas on the Ar gas outlet side is measured.

4. The method of producing a silicon single crystal ingot, according to claim 1, wherein the gas concentration of the dopant gas is measured using a mass spectrometer.

5. The method of producing a silicon single crystal ingot, according to claim 1, wherein the n-type dopant is one of Sb and As.

6. A silicon single crystal growth apparatus comprising: a crucible storing a silicon melt doped with an n-type dopant; a lifting and rotating mechanism which is provided on a lower end of the crucible to rotate, raise, and lower the crucible; a chamber accommodating the crucible; a pressure regulator controlling a pressure in the chamber; a pulling portion pulling up a silicon single crystal ingot from the silicon melt by the Czochralski process, a gas supply for supplying Ar gas into the chamber; a gas exhaust through which the Ar gas is discharged from the chamber; and a guide portion provided above a surface of the silicon melt for guiding the Ar gas to flow along the surface of the silicon melt, further comprising a measurement unit for measuring the gas concentration of the dopant gas containing the n-type dopant as a constituent element discharged with the Ar gas on the Ar gas outlet side.

7. The silicon single crystal growth apparatus according to claim 6, wherein the measurement unit is a mass spectrometer.

8. The silicon single crystal growth apparatus according to claim 6, further comprising a control unit controlling the lifting and rotating mechanism, the pressure regulator, the pulling portion, the gas supply, and the measurement unit, wherein one or more pulling condition values including at least one of the pressure in the chamber, a flow volume of the Ar gas, and a gap between the guide portion and the silicon melt are controlled using the control unit while performing the pulling so that the gas concentration measured by the measurement unit falls within a target gas concentration range.

9. The silicon single crystal growth apparatus according to claim 6, wherein the n-type dopant is one of Sb and As.
